(19) United States
(12) Patent Application Publication
(10) Pub. No.: US 2016/0322942 A1
(43) Pub. Date: Nov. 3, 2016

(54) IMPROVED MATCHING TECHNIQUES FOR WIDE-BANDGAP POWER TRANSISTORS

(71) Applicant: DIAMOND MICROWAVE DEVICES LIMITED, Redvers Close, Leeds Yorkshire (GB)

(72) Inventors: Richard LANG, Baildon (GB); Jonathan GILL, Clayton, Bradford (GB); Damian GOTCH, Baildon, Shipley (GB); Richard HILTON, Leeds (GB)

(73) Assignee: DIAMOND MICROWAVE DEVICES LIMITED, Redvers Close Leeds, Yorkshire (GB)

(21) Appl. No.: 15/108,937

(22) PCT Filed: Dec. 31, 2014
(86) PCT No.: PCT/GB2014/053859

§ 371 Date: Jun. 29, 2016

(30) Foreign Application Priority Data
Dec. 31, 2013 (GB) 1323159.2

(51) Int. Cl. H03F 1/56; H03F 3/21; H01L 25/07; H01L 23/64; H01L 23/00; H01L 23/498; H03F 3/193; H01L 23/66

(52) U.S. Cl. CPC H03F 1/565; H03F 3/193; H03F 3/21; H01L 23/66; H01L 23/645; H01L 23/647; H01L 24/49; H01L 24/17; H01L 23/49838; H01L 25/072; H03F 2200/451; H01L 2223/6611; H01L 2223/6627; H01L 2223/6655; H03F 2200/222; H01L 2224/04042; H01L 2224/16225; H01P 3/026

(57) ABSTRACT

Some embodiments of the present invention provided an impedance-transforming arrangement comprising a plurality of microwave power transistors 41, and at least one intermediate impedance-transforming or matching device 30. The matching device comprises a plurality of elongate microwave transmission lines 31 provided in or on at least one dielectric substrate 32, extending across or through the dielectric substrate. The microwave transmission lines are coupled at one end to the gate pads 47 of the transistor and at the input ends to a signal input terminal for the transmission line. The transmission lines are substantially directly coupled to one another by means of resistive elements 35 providing a current flow path between the two transmission lines in order to reduce any residual tendency to instability caused by manufacturing variations or misalignment in the assembly process.

The present application is directed to the pre- and post-matching of discrete microwave power transistors to improve power amplifier performance.

### BACKGROUND

Microwave power amplifiers using discrete (unpackaged) wide bandgap transistors can be realised in a hybrid arrangement, either using a single transistor or using several such transistors combined (in parallel) and assembled with specific separate passive electronic components to achieve a prescribed level of performance. This hybrid microwave integrated circuit (MIC) realisation is often preferred to an integrated solution (such as a microwave monolithic integrated circuit or MMIC), as it can lead to much improved performance through the use of higher “Q” external embedding electronic components. A requirement of the MIC arrangement is that the discrete transistors are connected to input and output matching networks or components through the use of many bond wires. The output of each transistor comprises a large number of intrinsic parallel feeds, and therefore has low impedance (when compared with a low-power transistor), while the input comprises a large number of gates, and therefore has relatively high capacitance (when compared with a low-power transistor). It can therefore be difficult to provide a suitable impedance match between the transistor and its embedding circuits which provides good power transfer across a required band of frequencies. Such a match requires the application of prescribed inductive and capacitive reactances.

Bond wires in MIC devices are used to connect together individual discrete components and are typically short lengths (say 50-500 μm) of thin (say 25 μm diameter), high-conductivity (often gold or aluminium) wires that are assembled using conventional wire-bonding equipment. These bond wires have an inductive reactance that increases with operating frequency (X_{L}=ωL, where X_{L} is the inductive reactance, w is the frequency and L is the length of the bond wire) and which is critically dependent upon the length and orientation of the wire.

This, however, results in a problem: designs that use bond wires to form part of the inductance of an impedance transformation are susceptible to performance variation from bond wire manufacturing production tolerance. In particular, the inductance provided by a bond wire is critically determined by its length and shape, and even slight variations in bond wire length or orientation can lead to changes in inductance, especially at high frequencies. For example, variations in bond wire length that may not present a particular problem at 2 GHz may become rather more problematic at 20 GHz, where its reactance is a factor of 10 higher for the same length of wire.

The bond wire inductance, being part of the overall hybrid amplifier circuit, needs to be accurately controlled to ensure repeatable and high-yielding circuit performance. Some consistency and control may be achieved through the use of automated wire bonding techniques, but this is not always possible for low-volume production runs, and the wire lengths are still subject to a specific manufacturing tolerance.

One problem therefore is how to overcome the inherent performance variation (and consequent limitation on manufacturing yield) from an MIC power amplifier which uses bond wires with potentially randomly or systemic varying dimensions within the important embedding matching networks. In other words, how to reduce significantly the sensitivity of the performance of such an amplifier to manufacturing variations in the bond wires used in the amplifier matching networks. GB 2489814 by the present applicant, the content of which is hereby incorporated by reference, discloses a solution to this problem by providing an intermediate impedance-transforming device comprising one or more microwave transmission lines each having a predetermined series inductance per unit length and, in combination with an electrically isolated conductive plate or layer, a predetermined capacitance per unit length. The transmission line may for example be provided by a length of microstrip transmission line. The impedance of the bond wire is absorbed into the impedance per unit length of the microwave transmission line.

In addition, there is a need to implement matching networks that can accommodate the low output impedance and high input reactance of wide bandgap transistors (although the same problem can also exist with other conventional FET devices). This can be achieved through the use of external “lumped” shunt capacitive matching elements (chip capacitors) as impedance transformers, but these require close attention to the effect of extrinsic bond wire inductance. An example of such a matching network is known from EP 2197030, which discloses a high frequency semiconductor device taking the form of a field effect transistor (FET) with multiple parallel inputs and multiple parallel outputs, each realised by a plurality of bond wires. Some of the structures disclosed in GB 2489814 are capable of providing such matching networks.

Another problem is that lumped designs which use separate inductors (bond wires) and chip capacitors to implement an impedance transformation have an inherent bandwidth limitation when compared with the use of a distributed network, unless the number of capacitive and inductive stages is increased. Again, some of the structures disclosed in GB 2489814 are capable of overcoming this problem at least in part.

It is an aim of the present invention to address disadvantages associated with the prior art.

### SUMMARY OF THE INVENTION

Embodiments of the invention may be understood with reference to the appended claims.

Aspects of the present invention provide a power amplifier, a system and a method.

In an aspect of the present invention for which protection is sought there is provided an impedance-transforming device for a microwave power transistor, comprising:
a plurality of elongate microwave transmission lines provided in or on at least one dielectric substrate, each transmission line having a length, the microwave transmission lines extending at least partially across or through the at least one dielectric substrate, the microwave transmission lines having:
   a first end for coupling to the microwave power transistor; and
   a second end for providing a signal input terminal for the transmission line,
the transmission lines having a predetermined series inductance per unit length and, in combination with one or more electrically isolated conductive plates or layers, a predetermined shunt capacitance per unit length, such that the length of microwave transmission lines together with the one or more conductive plates or layers have a predetermined characteristic impedance and phase constant,
wherein at least first and second transmission lines of the plurality of transmission lines are substantially directly coupled to one another by means of at least one resistive element, the resistive element providing a current flow path between the two transmission lines.

The presence of the resistive element has the advantage that, in use, unwanted frequencies of oscillation of the microwave power transistor may be suppressed. That is, they may be attenuated, quenched or prevented from occurring.

It is to be understood that the at least one resistive element is provided in addition to any parasitic resistances that may exist between respective elongate microwave transmission lines.

Resistive elements within impedance-matching arrangements have been proposed, as for instance in U.S. Pat. No. 6,741,144 by Matsushita. However, here they are used to connect two halves of a “distributed constant line”, serving an entire FET and in the form of a λ/4 plate, that has been split into two in order to suppress circulating currents. With embodiments of the invention, the transmission lines are so narrow that no transverse effects occur.

The microwave transmission lines may each have a first end coupled to a gate pad of the microwave power transistor. Ideally there is one transmission line for each gate pad, connected by a short bond wire, or perhaps two or more if there is space. The spacing of the gate pads in a typical power transistor will generally be of the order of 200 μm, so the transmission lines in embodiments of the invention will be spaced at about this inventorial.

Moreover, the transmission lines in some embodiments are spaced from each by an amount comparable to—say between half and twice—their width, so that in such embodiments they will be about 100 μm wide. In this way, the input to each gate pad is exactly the same, greatly reducing the edge effects that are prone to arise when wide plates are used, covering several gate pads.

The transmission lines may be in the form of elongate bar capacitors in some embodiments, one electrode of each bar capacitor providing or defining a transmission line for the propagation of a microwave frequency signal therealong. Preferably the aspect ratio of the bars is at least 2, further preferably at least 3 or even at least 4. In this way, the width (i.e. across the transmission direction) is still small compared to the wavelengths typically used.

It is to be understood that the second end of each transmission line may be coupled to a bond pad or other terminal feature. However the second end still may still be considered to provide a terminal for the transmission line, whether or not it is coupled to a further terminal such as a bond pad.

The present applicant has found that by providing at least one resistive element connecting at least first and second transmission lines of the plurality of transmission lines of the intermediate impedance-transforming device, unwanted oscillations in microwave signals generated by the microwave power transistors may be suppressed. This is at least in part because the intermediate impedance-transforming device is configured so that if a potential difference exists across the resistive element a current may flow between the transmission lines via the resistive element, damping one or more signals flowing through one or more of the transmission lines and so preventing the build-up or formation of an oscillation.

Some embodiments of the present invention have the advantage that “odd-mode” damping may be performed in a convenient manner, reducing or eliminating unwanted signal oscillations. In addition or instead, some embodiments have the advantage that wanted pass-band signals may be stabilised by attenuation thereof. As described below, one or more characteristics of the arrangement may be determined at least in part by careful selection of the location(s) along the transmission lines at which the at least one resistive element is coupled to each of the transmission lines.

Optionally, the at least one resistive element is coupled to the first transmission line a first distance from the signal input terminal thereof and to the second transmission line a second distance from the signal input terminal thereof.

The first and second distances may be substantially equal.

Alternatively the first and second distances may be not substantially equal.

The first and second distances may correspond to substantially equal electrical lengths.

Reference to the first and second distances corresponding to substantially equal electrical lengths is understood to mean that a signal of a given frequency will take substantially the same amount of time to travel the first distance along the first transmission line as it would take to travel the second distance along the second transmission line. For substantially identical transmission lines the electrical lengths will be substantially equal if the first and second distances are substantially equal.

This feature has the advantage that odd-mode signals propagating along one transmission line may be attenuated or eliminated. This is because an odd-mode signal propagating along one transmission line and an even mode signal propagating along another transmission line will induce a potential difference across the resistive element resulting in current flow and hence power dissipation in the resistive element.

Optionally, the first and second distances do not correspond to substantially equal electrical lengths.

The feature that the first and second distances correspond to different electrical lengths has the advantage that signals of substantially identical frequency and phase propagating along respective transmission lines may be attenuated. This is because such signals will induce a potential difference across the resistive element resulting in current flow and hence power dissipation in the resistive element.

Optionally, the plurality of elongate microwave transmission lines are provided in a spaced apart side by side relationship, respective adjacent transmission lines being coupled to one another by means of the at least one resistive element.

Optionally, a resistive element is provided between each transmission line and at least one neighbouring transmission line.

Optionally, a resistive element is provided between each transmission line and its neighbouring transmission line(s).

Optionally, the transmission lines are provided in a substantially parallel spaced apart side-by-side relationship.

Optionally, the device is coupled at the first end thereof to the microwave power transistor by means of a bondwire. Optionally, the bond wire has a specified minimum practical length with an associated impedance. The impedance of the bond wire may be absorbed into the series impedance of the microwave transmission line.

It is to be understood that by the term ‘absorbed’ is meant that variations in inductance of the extrinsic bond wires due to slight variations in the lengths and attachment points of the extrinsic bond wires are minor compared to the overall inductance provided by the transmission lines. Optionally, by the term ‘minor’ is meant that a variation in inductance associated with the bondwires and points of attachment due to manufacturing tolerances in the fabrication process is less than or substantially equal to a predetermined proportion of the inductance provided by the transmission lines. The predetermined proportion may be 10%, 5%, 1% or any other suitable proportion.

Optionally, the intermediate impedance-transforming device is mounted upside down in a ‘flip-chip’ manner with respect to the microwave power transistor and coupled at the first end thereof to the microwave power transistor by means of a solder bump.

Optionally, the plurality of microwave transmission lines are provided on at least one dielectric substrate.

The plurality of transmission lines may be provided on a single substrate. Alternatively the plurality of transmission lines may be provide on a plurality of substrates. For instance, in an assembly where an array of FETs is used, there may be one substrate for all the transmission lines to a single transistor. This leads to reasonably simple alignment in the manufacturing process. The transmission lines may however all be deposited on the same substrate. Optionally, each transmission line, or subsets of the transmission lines for a transistor, may be provided on a different respective substrate.

Optionally, the at least one substrate has a dielectric constant greater than 10, preferably greater than 13, optionally at least 40.

Optionally, each microwave transmission line comprises a conductive microstrip transmission line.

Further optionally, each microwave transmission line comprises a coplanar waveguide.

Optionally, each microwave transmission line comprises a conductive strip line transmission line.

Optionally the at least one intermediate impedance-transforming device comprises a generally oblong slab of dielectric substrate with first and second opposed major surfaces, the first surface being metalized and the second surface bearing at least one microwave transmission line extending thereacross.

Optionally, one said at least one dielectric substrate is provided with a plurality of substantially parallel microwave transmission lines extending thereacross or therethrough.

Optionally, each microwave transmission line gives rise to substantially the same predetermined characteristic impedance and phase constant.

Alternatively the microwave transmission lines may be configured so as to give rise to different predetermined characteristic impedances and phase constants.

Optionally, the microwave power transistor is provided on a first dielectric substrate having a first dielectric constant, the at least one dielectric substrate of the impedance-transforming device having a dielectric constant greater than the first dielectric constant.

Optionally the at least one intermediate impedance-transforming device is located on a gate terminal or input side of the transistor.

Alternatively the at least one intermediate impedance-transforming device may be located on a drain terminal or output side of the transistor.

Optionally at least one intermediate impedance-transforming device is located on a gate terminal or input side of the transistor, and wherein at least one intermediate impedance-transforming device is located on a drain terminal or output side of the transistor.

Optionally, at least one intermediate impedance-transforming device located on a gate terminal or input side of the transistor has a different predetermined characteristic impedance, and preferably also phase constant, to at least one intermediate impedance-transforming device located on a drain terminal or output side of the transistor.

Optionally the first end of each microwave transmission line is electrically connected to a respective transistor by a connection that is shorter in length than the microwave transmission line.

In a further aspect of the invention for which protection is sought there is provided a method of impedance matching to a microwave power transistor, whereby at least first and second microwave transmission lines are each connected at a first end thereof to a gate or drain terminal of a respective transistor, the at least first and second microwave transmission lines extending across or through a dielectric substrate, the microwave transmission lines each having a predetermined series inductance and, in combination with an electrically isolated conductive plate or layer, a predetermined shunt capacitance such that each microwave transmission line together with the conductive plate or layer has a predetermined characteristic impedance and phase constant, the method comprising coupling the first and second transmission lines substantially directly to one another by means of at least one resistive element, the at least one resistive element providing a current flow path between the two transmission lines.

The at least one resistive element may provide a current flow path between respective locations of the two transmission lines that are spaced apart from respective opposed ends thereof of the transmission lines.

The method may comprise providing at least first and second microwave transmission lines each connected at a first end thereof to a gate or drain terminal of each transistor, then depositing resistive material to bridge the gap between adjacent transmission lines.

It is to be understood that at least one of the plurality of transmission lines may be provided on a separate respective dielectric substrate to the others. Optionally, each of the plurality of transmission lines may be provided on a separate respective dielectric substrate.

Optionally the at least first and second microwave transmission lines are connected at the first end thereof by means of a bond wire to the gate or drain terminal of the transistor, wherein an impedance of the bond wire is absorbed into the series impedance of the microwave transmission line to which it is connected.

Viewed from another aspect, there is provided an intermediate impedance-transforming device for a microwave power transistor, the device comprising: a dielectric substrate bearing or containing a plurality of elongate microwave transmission lines each having a length and extending across or through the substrate, the microwave transmission lines each having a first end and a second end, a predetermined series inductance per unit length and, in combination with an electrically isolated conductive plate or layer, a predetermined shunt capacitance per unit length, such that each length of microwave transmission line together with the conductive plate or layer has a predetermined characteristic impedance and phase constant; the device being configured such that, when a bond wire of a specified minimum practical length with an associated impedance is connected between an end of one of the microwave transmission lines and a microwave power transistor, the impedance of the bond wire is absorbed into the impedance per unit length of the microwave transmission line, wherein at least first and second transmission lines of the plurality of elongate transmission lines are substantially directly coupled to one another by means of a resistive element, the resistive element providing a current flow path between the two transmission lines.

Viewed from another aspect, there is provided an impedance-transforming arrangement comprising a plurality of microwave power transistors, the plurality of microwave power transistors being formed on one or more first dielectric substrates having a first dielectric constant, and at least one intermediate impedance-transforming device of the previous aspect.

The invention envisages an impedance-transforming arrangement in combination with a microwave power transistor, the impedance-transforming arrangement comprising a matching network formed on a first dielectric substrate having a first dielectric constant, and at least one intermediate impedance-transforming device. The substrate of the latter may have the same or a different dielectric constant, and in the first case may be the same substrate.

Viewed from yet another aspect, the present invention provides a method of impedance matching to a microwave power transistor, wherein a plurality of microwave transmission lines are connected by bond wires each having an impedance to a gate or drain terminals of the transistor, the microwave transmission lines extending across or through a dielectric substrate, the microwave transmission lines having a predetermined series inductance and, in combination with an electrically isolated conductive plate or layer, a predetermined shunt capacitance such that each microwave transmission line together with the conductive plate or layer has a predetermined characteristic impedance and phase constant, and wherein the impedance of each bond wire is absorbed into the impedance of the microwave transmission line to which it is connected. The method further comprises substantially directly coupling at least two of the transmission lines to one another by means of a resistive element, the resistive element providing a current flow path between the two transmission lines. The resistive element may be coupled to each of the at least two transmission lines at a location that is spaced apart from one or both ends of the respective transmission lines.

In typical embodiments, the impedance matching device comprises an array of microwave transmission lines arranged side-by-side in parallel formation. Each line may have the potential to affect its neighbouring line or lines by electromagnetic coupling and may therefore modify its effective capacitance or inductance per unit length. The array may be provided on a gate side of the transistors or a drain side of the transistors, or two arrays may be provided, one on each side of the transistors for pre- and post-matching. In some embodiments the array provided on the drain side may be arranged not to be provided with the resistive elements coupling respective transmission lines. Each array may be formed on one piece of dielectric substrate, or several arrays each on a separate piece of dielectric substrate may be provided on one or other or both sides of the transistor. The device may be manufactured as a single part (for each side of the transistor), or several identical parts could be deployed in side-by-side formation.

An impedance-transforming device according to an embodiment of the present invention, comprising distributed inductance and capacitance, may be seen or configured as an array of bar capacitors, typically taking the form of a rectangular dielectric substrate having first and second substantially parallel major surfaces, with metallization on the first and second surfaces to form the plates of the capacitor. The metallization on one surface may be over substantially the whole surface, while the metallization on the other opposed surface may take the form of a plurality of microwave transmission lines in the manner of conductive microstrip transmission lines or coplanar waveguides.

The overall shape of each transmission line may be bar shaped (long, flat and thin), hence the name bar capacitor. The microwave transmission lines typically extend along substantially the whole length of the rectangular dielectric substrate.

In some embodiments the metallization forming a ground plane may be provided on the first and/or second major surfaces with a plurality of transmission lines disposed through the dielectric substrate, optionally in the form of stripline transmission lines.

A particular advantage of a device of the type described herein is that the microwave transmission lines incorporate inductance, as well as a capacitance. By carefully selecting the width and length of the microwave transmission lines (whether embedded in a dielectric substrate or provided at a major surface), along with their spacing from the opposed metalized surface and the dielectric constant of the dielectric material, it is possible to form an impedance matching component with well-defined inductance and capacitance per unit length (or impedance). Because the lengths of the microwave transmission lines, which primarily defines the inductance, is well defined (since they typically run from one end of the dielectric substrate to the other), the inductance is well defined. Moreover, by performing the impedance matching primarily in the bar capacitor array, rather than in external, “lumped” shunt capacitors, the lengths of any extrinsic bond wires may be significantly reduced. Indeed, the minimum length required to join each distributed or bar capacitor to the respective transistor or group of transistors would normally be employed, and this finite bond wire inductance would be absorbed into the matching network, in particular the intermediate impedance-transforming device. This means that slight variations in the lengths and attachment points of the extrinsic bond wires are minor compared to the overall inductance as provided by the bar capacitor array (the major part of this being the microstrip transmission lines).

Another advantage is that the dielectric substrate of the device may be made of a material with a higher dielectric constant than that of generic PCB substrates such as FR4 or Duroid® or the like. In a monolithic environment such as an MMIC using GaAs, the dielectric constant of the monolithic substrate is around 12.9. The device of present embodiments can be made with high dielectric constant substrates having a dielectric constant higher than 12.9, for example 13, 20, 30, 40 or higher, and in some variants less than 300. The strip line can then be shorter for the same impedance.

Certain embodiments of the device may be viewed in terms of (short) lengths of transmission line utilising a material with a high dielectric constant (high with respect to that which would normally be used if a monolithic environment was used—as in an MMIC for instance). The device in effect replaces a lumped capacitor with finite lengths of a “microstrip” transmission-line, which in its simplest form can be modeled as a serial cascade of unit elements which take the form of a series inductor and a shunt capacitor. It is also possible that a “coplanar waveguide” or other similar transmission line type could be employed as noted above. In essence, the total line capacitance replaces the lumped capacitance, but the added benefit is that the additional “distributed” inductance can be used in the matching solution. The impedance of a transmission line may be defined as the square root of the inductance per unit length divided by the capacitance per unit length, and this is used in the matching solution. The use of a separate, or “discrete” transmission line in this way, with a substrate of high dielectric constant (say 13, 40 or higher, although in some embodiments not exceeding 300), allows the use of a higher capacitance per unit length than would be achievable on a planar integrated circuit (say with a dielectric constant of 12.9 for GaAs) and leads to a more compact and more versatile impedance-transforming network.

In some embodiments, one major surface of a dielectric substrate is completely or substantially wholly metalized, while the opposed major surface is provided with an array of parallel metalized tracks in the form of microwave transmission lines.

It is difficult, if not impossible, to avoid coupling between adjacent microwave transmission strips, but it is relatively straightforward to compensate therefore if the amount of coupling can be reliably determined. Since the microwave transmission line strips can be printed or photolithographically etched or otherwise formed on the dielectric substrate using high-precision techniques so as to be evenly and regularly spaced, the coupling is predictable.

This is in contrast to an array of individually located bond wires that may not be so evenly or regularly spaced.

Certain embodiments of the present invention seek to absorb the inherent and necessary bond wire inductances (as connected to the gate and drain connections on a microwave power transistor) into a custom, high dielectric constant, capacitor array in either (or both) of the pre-and post-matching networks of discrete microwave wide-bandgap power transistors.

A bar capacitor array (FIG. 2(a)), in contrast to a lumped capacitor and pair of bond-wires (FIG. 1), effectively “absorbs” the required matching inductance and reduces significantly the amount of inductance that is required in the wire bond—the latter being susceptible to manufacturing variances and tolerances. The bar capacitor array can be manufactured using precise photolithographic techniques, and is very repeatable (or can be selected to have a prescribed small tolerance) and reduces the reliance on high-tolerance manufacturing of the more difficult bond-wire approach.

The bar capacitor array can also utilise a wide range of high-dielectric-constant materials, to allow a designer to seek to optimise the matching impedance. Additionally, by utilising a printed or etched “array” of capacitors on a single substrate, the input and output connections to the multiple gate and drain connections of the power transistor or transistors can also be better controlled—which includes the reactance as applied to each device terminal, and also the electromagnetic coupling between capacitive elements (which would normally be separately assembled).

The overall effect of utilising a distributed or bar-capacitor array in this manner is to improve the performance and manufacturing yield of a microwave power amplifier when compared with a conventional lumped-element or discrete chip realisation.

This technique is expected to increase the manufacturing yield of such amplifiers, leading to a reduction in manufacturing cost of the finished product. Additionally, this technique is expected also to improve the overall bandwidth performance when compared with more conventional lumped element matching techniques.

An additional advantage of certain embodiments is that it is easy to assemble a matching network with reliable and reproducible matching properties by simply aligning proximal ends of the bar capacitor array close to the edges of the microwave power transistors when mounting on a circuit board substrate. This can be done on both the gate and the drain sides of the microwave power transistors, and further reduces the margin for error due to inconsistent bond-wire lengths. By aligning proximal ends of the bar capacitor array close to the edges of the transistors before connecting to the drain or gate terminals of the microwave transistors, correct orientation of the microwave transmission lines is facilitated, and only short pieces of bond wire need to be used to connect the microstrip transmission lines to the respective transistor terminals. Indeed, since the distance between the end of each microstrip transmission line and its respective transistor terminal is more or less the same, identical lengths of bond wire can be used. In some embodiments, it may be possible to abut the proximal ends of the bar capacitor arrays to the edges of the microwave transistors, but most often there will be a small gap due to the methods used for placing and affixing the components onto a circuit board or other substrate. In particular, the use of epoxies or solders and die handling collets may make it difficult to abut the proximal ends of the bar capacitor arrays so that they actually touch the edges of the transistor component.

In some embodiments, the intermediate impedance-transforming devices may be mounted upside down in a “flip-chip” manner between the power transistors and external embedding networks, with the power transistors and the external networks being fabricated on the same dielectric substrate (for instance as in a monolithic integrated circuit). In such an arrangement, the extrinsic bond wires may be replaced with “solder bumps”, conductive epoxy or preformed conductive tracks or a similar attachment method, and attachment to the ground plane of the device could be by conductive via connections within the device or by a “wrap-around” connection on the edge of the device.

In summary, embodiments of the present application work by absorbing or making negligible the inductance of any necessary bond wires into a well-defined series inductance of a precisely manufactured microwave transmission line on a dielectric substrate, and by providing a shunt capacitance to this series inductance by way of an opposed plate or metallization. A resistive element is provided between at least a pair of transmission lines so as to allow current flow between them when a non-zero potential difference arises across the resistive element. Optionally, and advantageously, a resistive element may be provided between all adjacent transmission lines. Improved capacitance per unit length may be obtained by using a dielectric substrate with a high dielectric constant, higher than that of substrates typically used in MMIC and MIC implementations. In this way, improved impedance matching to microwave power transistors is facilitated.

Some embodiments of the present invention provide an impedance-transforming arrangement comprising a plurality of microwave power transistors, and at least one intermediate impedance-transforming device. The device may comprise a plurality of elongate microwave transmission lines provided in or on at least one dielectric substrate, each transmission line having a length. The microwave transmission lines may extend at least partially across or through the at least one dielectric substrate. The microwave transmission lines may have: a first end coupled to one of the microwave power transistors; and a second end providing a signal input terminal for the transmission line. The transmission lines may have a predetermined series inductance per unit length and, in combination with one or more electrically isolated conductive plates or layers, a predetermined shunt capacitance per unit length, such that the microwave transmission lines together with the one or more conductive plates or layers each have a predetermined characteristic impedance and phase constant. At least first and second transmission lines of the plurality of transmission lines are substantially directly coupled to one another by means of a resistive element, the resistive element providing a current flow path between the two transmission lines.

### BRIEF DESCRIPTION OF THE DRAWINGS

Embodiments of the invention are further described hereinafter with reference to the accompanying drawings, in which:

FIG. 1 is a schematic diagram showing a prior-art lumped chip capacitor and extrinsic bond wire arrangement;

FIG. 2 shows (a) a schematic circuit diagram of a known distributed inductor capacitor network and (b) a cross-section through a physical embodiment of the network shown in (a);

FIG. 3 is a schematic circuit diagram of an impedance-transforming device according to an embodiment of the present invention;

FIG. 4 is a plot of potential as a function of distance from an input terminal of the impedance-transforming device of FIG. 3 in the case of
(a) two substantially identical signals propagating in phase along transmission lines 6A and 6B;
(b) two substantially identical signals propagating along transmission lines 6A and 6B with a relatively small phase difference phi therebetween; and
(c) two substantially identical signals propagating along transmission lines 6A and 6B with a phase difference of substantially 180°;

FIG. 5 is a schematic illustration of an impedance-transforming device according to an embodiment of the present invention in the form of a bar capacitor array;

FIG. 6 is a schematic diagram of a portion of a power amplifier circuit having an impedance-transforming device according to an embodiment of the present invention that couples an input signal feed to an input of a power transistor array;

FIG. 7 is a schematic illustration of an impedance-transforming device according to a further embodiment of the present invention in the form of a bar capacitor array;

FIG. 8 is a schematic illustration of an impedance-transforming device according to a still further embodiment of the present invention in the form of a bar capacitor array;

FIG. 9 is a schematic illustration of an impedance-transforming device according to another embodiment of the present invention in the form of a bar capacitor array; and

FIG. 10 is a plot of gain as a function of frequency in a power amplifier circuit according to an embodiment of the present invention for different values of the parameter s of FIG. 9.

### DETAILED DESCRIPTION

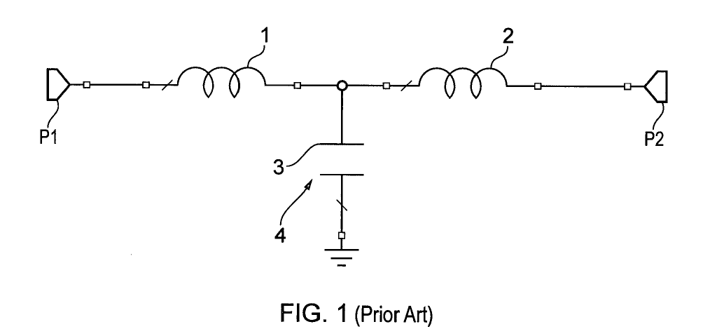

FIG. 1 shows a known impedance-transforming arrangement between two ports P1 and P2. The port P1 could represent an external circuit of impedance Z1 and the port P2 could represent the impedance as presented by a power transistor. This arrangement is similar to the impedance-transforming arrangement disclosed in EP 2197030. Two inductors in the form of bond wires 1, 2 connect a discrete or lumped capacitor 4 to, respectively, the external matching network and the power transistor. The first bond wire 1 connects the port P1 to one plate 3 of the lumped capacitor 4 and the second bond wire 2 connects plate 3 of the lumped capacitor 4 to the port P2. Bond wires 1 and 5 are each configured as inductors. By selecting appropriate inductance and capacitance properties, the impedances at ports P1 and P2 can be matched to each other for a given signal frequency. However, the inductance of each of the bond wires 1, 2 is primarily dependent on the length and configuration of each bond wire and, to some extent, its spatial orientation. These are difficult to control to desired tolerances when attaching bond wires manually under a microscope. Even when using automated bond wiring machines, it is difficult to achieve a sufficiently high degree of repeatability so as to obtain the best possible tolerances.

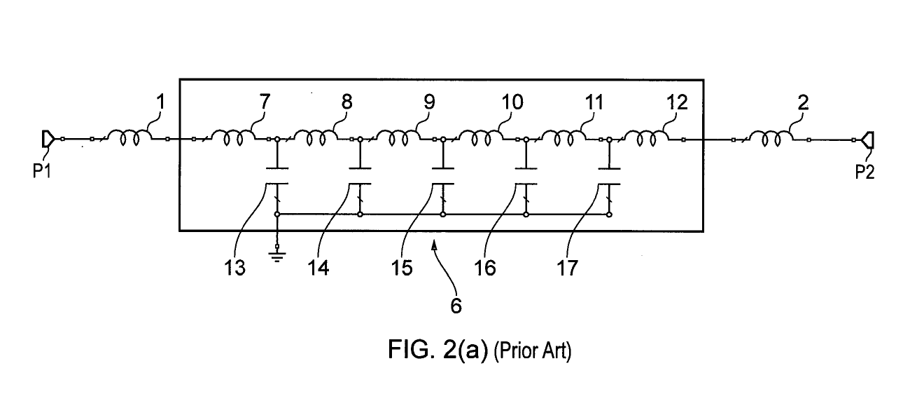

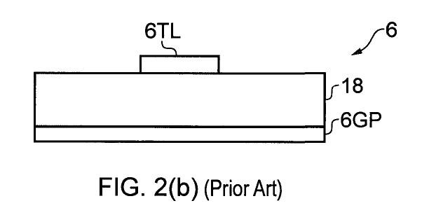

FIG. 2(a) shows, in schematic form, a known impedance matching device 6 disclosed in GB 2489814. Here, instead of a lumped capacitor 4 as shown in FIG. 1, a distributed capacitor inductor network or device 6 is utilised. The device 6 is shown in schematic form, and is equivalent to a series of well-defined inductors 7, 8, 9, 10, 11, 12 with interposed parallel capacitive connections 13, 14, 15, 16, 17 to ground. In actual construction terms, as shown in FIG. 2(b) the device 6 comprises an oblong slab of dielectric material 18 as a substrate, with a metalized underside 6GP providing a groundplane, and a microwave transmission line 6TL printed or etched or otherwise formed on the opposed topside, the microwave transmission line 6TL providing the series inductors 7-12. The ports P1 and P2 are still connected to the ends of the microwave transmission line 6TL by bond wires 1, 2, but these bond wires 1, 2 then form only a small part of the overall series of inductors 7-12, and any variance in the inductance of the bond wires 1, 2 has a correspondingly minor effect on the overall inductance of the device 6 as a whole.

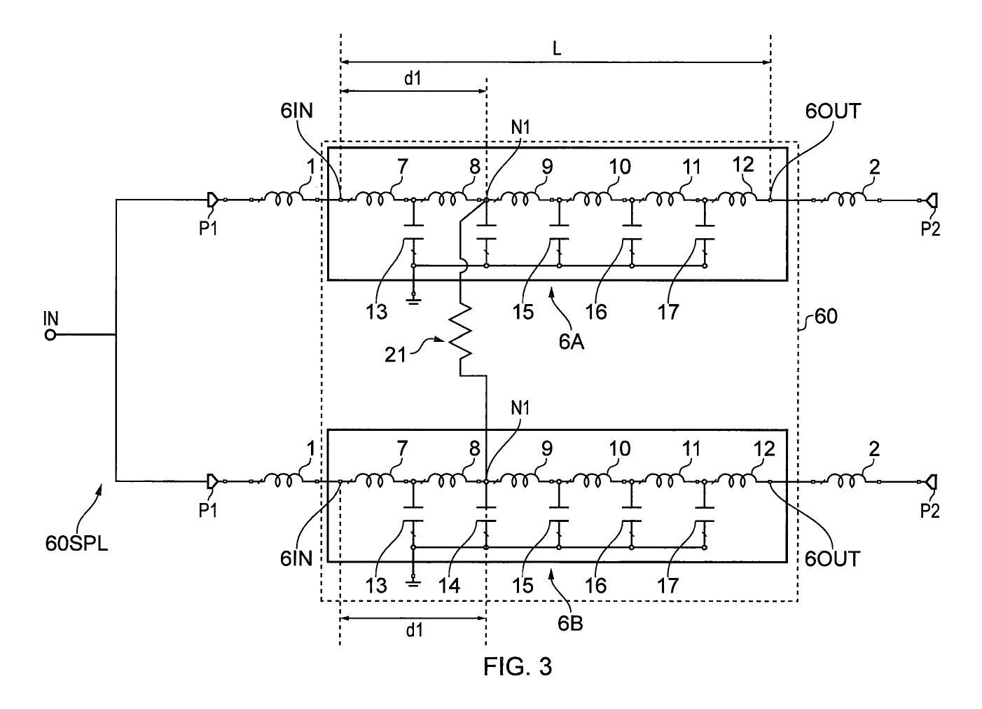

FIG. 3 shows an impedance matching device or structure 60 according to an embodiment of the present invention. The structure 60 has two of the impedance matching devices 6 of FIG. 2(a) provided in parallel. In the present embodiment the devices 6 share a common substrate but in some alternative embodiments they may be provided on separate respective substrates.

The devices 6A, 6B are shown coupled at their input terminals 61N to input ports P1 by means of bondwires 1. The input ports P1 are in turn coupled together by means of a splitter 60SPL. The splitter 60SPL has an input terminal IN that receives a signal to be amplified and divides the signal substantially equally between input ports P1.

The devices 6A, 6B are also coupled at their output terminals GOUT to output ports P2 by means of bondwires 2. The output ports P2 are in turn arranged to be coupled to respective transistor devices to amplify the signal applied to input port 61N. The respective transistor devices may be members of respective groups of two or more transistor devices. For example, each of the output ports P2 may be connected to a group comprising a plurality of microwave power transistor devices. For example each output port P2 may be connected to the gate terminals of each of a plurality of microwave power transistor devices.

As shown in FIG. 3 the devices 6A, 6B are coupled to one another by means of a resistor 21. The resistor 21 allows current flow between the devices 6A, 6B when a potential difference is established across the resistor 21. The resistor 21 is coupled to each device 6A, 6B at corresponding locations, being locations that are a distance d1 from input terminal 61N of each device 6A, 6B. In the embodiment shown in FIG. 3 the input terminals 61N correspond to a free end of the devices 6A, 6B nearest input ports P1. It is to be understood that d1 is non-zero and less than the distance L between input and output terminals 61N, GOUT.

It is to be understood that as a signal of a given frequency propagates along the transmission line 6TL provided by each device 6A, 6B, the signal induces a potential difference in the transmission line 6TL that varies as a function of distance along the transmission line 6TL from the input terminal 61N. FIG. 4(a)-(c) shows a series of plots of the potential V induced in the transmission line 6TL of device 6A (trace A) and device 6B (trace B) as a function of distance along the transmission line 6TL from the input terminal 61N at a given instant in time, in the absence of resistor 21. The traces are superimposed on one another to aid comparison.

In the case of the plot of FIG. 4(a), two substantially identical signals A, B were applied to the devices 6A, 6B respectively. The signals have substantially the same amplitude, frequency and phase and therefore plots of the potential induced in the transmission lines 6TL as a function of distance from the input terminal 61N of each transmission line 6TL overlap one another with substantially no offset between the plots. As a consequence, the potential of the transmission line 6TL of each device 6A, 6B at a given distance d from the input terminal 61N is substantially identical in each device 6A, 6B. A resistor 21 coupled between the transmission lines 6TL a distance d1 from the input terminal 61N will therefore have a potential difference of substantially zero thereacross as the signals A, B propagate through the respective devices 6A, 6B. Accordingly, in the absence of any other signals, substantially no current will flow through the resistor 21.

In the case of the plot of FIG. 4(b), the signals A, B are substantially identical except that the signal applied to device 6B leads that applied to device 6A by a phase angle φ (phi).

This angle may be referred to as the phase difference. Accordingly, the difference in potential of the transmission line 6TL of each device 6A, 6B a given distance d from the input terminal 61N will vary as a function of time. In the example shown in FIG. 4(b) it can be seen that at the instant in time represented by the plots, the potential a distance d1 along the transmission line 6TL of device 6A is VA whilst the potential a distance d1 along the transmission line 6TL of device 6B is VB, where VA>VB. Accordingly, a resistor 21 coupled between the transmission lines 6TL a distance d1 from the input terminal 61N would have a potential difference of substantially VA−VB thereacross at the moment in time represented by the traces of FIG. 4(b). The difference in potential causes a current to flow in the resistor 21, which thereby dissipates energy associated with the signals A, B. This has the effect of attenuating the signals A, B, and may substantially eliminate one or both of the signals, modifying the appearance of the trace of FIG. 4(b). In the case that one signal such as signal B is unwanted, and weaker than the other signal, signal A, this can result in the weaker signal, signal B, being suppressed by an amount sufficient to eliminate one or more problems associated with signal B. For example, attenuation or elimination of signal B may enable stability to be restored in an amplifier that would otherwise become unstable.

In the case of the plot of FIG. 4(c), the signal propagating along the transmission line 6TL of device 6B is substantially 180° out of phase with that propagating along transmission line 6TL of device 6A. As a consequence, relatively large differences in potential can be established between the transmission lines 6TL of devices 6A, 6B at a given distance there along. In the example shown in FIG. 4(c) it can be seen that the difference in potential is substantially equal to |VA|+|VB|1. For signals of substantially the same amplitude the difference in potential is substantially 2VA.

It is to be understood that a scenario in which the phase difference between two signals is substantially 180° may be not uncommon in some applications, the signal passing through device 6B being an ‘odd mode’ of the signal passing through device 6A. Odd mode signals may be highly undesirable and their attenuation or elimination may be advantageous in some embodiments.

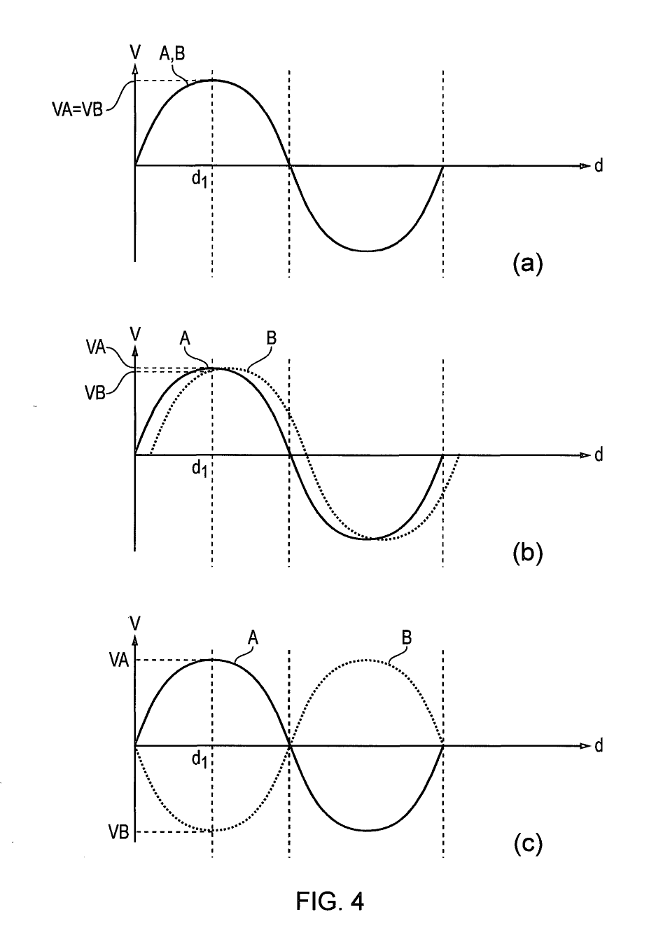

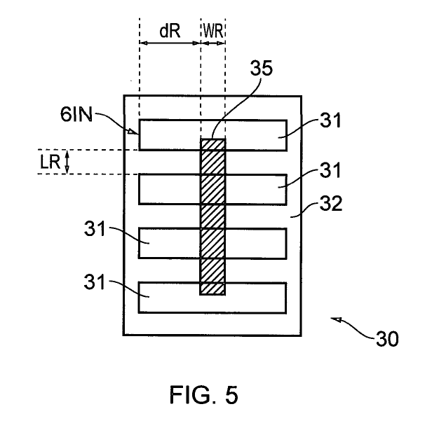

FIG. 5 shows a device 30 according to an embodiment of the present invention comprising a 1×4 array 30 of generally parallel highly conductive capacitor strips 31 (for example, microstrip transmission lines) printed or etched onto a top surface of a substrate 32 in the form of a rectangular slab of a dielectric material with a high dielectric constant (for example a dielectric ceramic material). In the example shown the dielectric material has a dielectric constant of around 40. Other materials are also useful. The underside of the substrate 32 is coated with a highly conductive groundplane (not shown).

An elongate resistive element 35 of substantially rectangular shape in plan view (as viewed in a direction normal to the substrate 32) has been formed over the substrate 32 and strips 31. The element 35 is of width WR and is spaced from the input terminal 61N of the device 30 by a distance dR. The element 35 has a sheet resistance Rs and a length of the element 35 between transmission lines 31 is LR. Accordingly, the resistance provided by the element 35 between transmission lines is given by the expression R=Rs(LR/WR). The value of R is selected so as to provide sufficient attenuation or suppression of unwanted signals.

The resistive element 35 provides a conductive path from each transmission line 31 to its neighbouring one or two transmission lines 31. It is to be understood that a potential difference induced across any portion of the resistive element 35 due to flow of signals A, B in adjacent transmission lines 31 may induce current flow in the resistive element 35 and therefore attenuation of one or both of signals A and B. One or both of the signals may be substantially eliminated in some situations.

In the embodiment of FIG. 5 the resistive element 35 is provided by a layer of carbon ink printed onto the array of bar capacitors 31 and substrate 32. Other materials are also useful for forming the resistive element, such as a layer of NiCr, TaN or any other suitable material. For example, a NiCr ink may be printed over the array of bar capacitors 31 and substrate 32 to form the resistive element 35. In embodiments with more than one substrate 32, it may be expedient to form one such resistive track on each substrate. In some embodiments the resistive element 35 may be formed from a discrete component that may be soldered or otherwise electrically connected to the capacitors 31, typically via solder pads. In some embodiments the resistive element 35 may be formed substantially only in the regions between bar capacitors 31, such that it does not extend across each bar capacitor 31 from one side to the other in the manner shown in FIG. 5. In some embodiments the resistive element or elements 35 may be formed before the conductors forming the transmission lines 31 are deposited. Other arrangements are also useful.

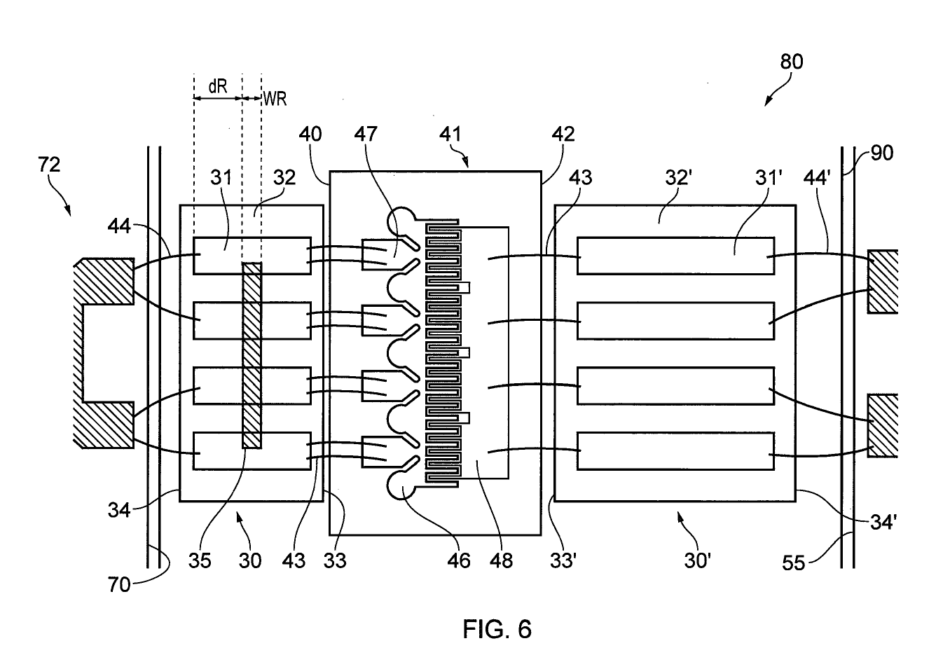

FIG. 6 shows a power amplifier 80, or at least its FET core, according to an embodiment of the present invention in which a first 1×4 array 30 of capacitor strips 31 (forming transmission lines 31) of the type illustrated in FIG. 5 is provided on the input side 40 of a microwave power transistor 41. This transistor can be of known type, made for instance on a substrate of GaAs or GaN or other III-V material, Si, SiC and so on. GaN in particular presents an impedance-matching problem. A further 1×4 array 30′ of transmission lines is provided on the output side 42 of the transistor 41. The array 30′ provided on the output side 42 differs from that provided on the input side 40 in that it is not provided with the elongate resistive element 35. Proximal ends 33, 33′ of each array 30, 30′ are aligned with the edges of the transistor 41 so that only short lengths of extrinsic bond wires 43 are needed to connect each capacitor strip 31, 31′ to its associated terminal on the transistor 41. The distal ends 34, 34′ of each array 30, 30′ face the respective network patterns on either side of the transistor 41 that are standard in microwave power transistor arrangements, and are connected thereto with relatively short lengths of bond wire 44, 44′.

The transistor 41 has source metallization for source, gate and drain, shown schematically at 46, 47 and 48, connected to interdigitated electrodes defining the channel. In this embodiment the transistor has four gate pads interleaved with five source pads, while the drain pad is a single wide pad 48. The source pads are connected by way of vias, not shown, to the underside of the substrate. The gate pads 47 are here connected by respective pairs of bond wires 43 to the transmission lines 31, the doubling being useful, if there is space, to reduce the inductance of the wirebonds still further. The number of transmission lines 31′ on the output side does not need to be the same as on the input side, but it is convenient.

Although the embodiment of FIG. 6 shows each array 30, 30′ with the capacitor strips (microstrip transmission lines) 31, 31′ uppermost on the exposed face of their respective dielectric substrates 32, 32′, it is possible in an alternative embodiment to mount the arrays 30, 30′ upside down. In such an arrangement, known in the industry as a “flip chip” arrangement, it may be possible to dispense with the bond wires completely and rely on solder bumps, conducting epoxy and/or preformed conductive tracks to form the electrical connections from the matching network through the arrays 30, 30′ and to the transistor 41.

Although not shown in FIG. 6, in a typical embodiment there would be two or more such transistors 41 arranged side-by-side on a common substrate 50, e.g. of copper, each with its own impedance-transforming device 30, though these could in principle be arranged on a common substrate. Since the characteristics of transistors can vary, even from the same wafer, this allows precise “tuning” for each transistor, using the resistors 35. The external or primary matching circuit 72 on the input side, including the splitter, is mounted on a substrate 70, which has a dielectric constant of less than 13, preferably less than 10, and usually ranging from 2 to 6, while the transistor arrangement is mounted on a copper substrate 90 and the output matching circuit is on a substrate 55.

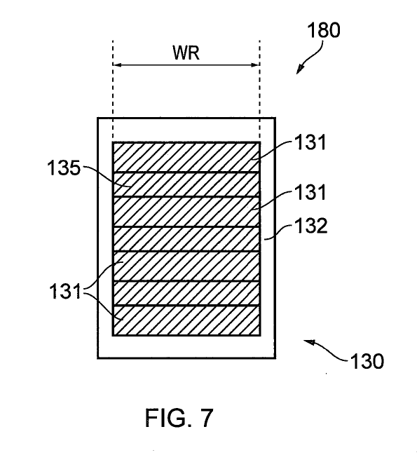

FIG. 7 shows an impedance-transforming device 130 according to a further embodiment of the present invention. Like features of the embodiment of FIG. 7 to those of the embodiment of FIG. 5 are shown with like reference signs prefixed numeral 1. The device of FIG. 7 is similar to the embodiment of FIG. 5 except that the resistive element 135 of the embodiment of FIG. 7 has a width corresponding to substantially the whole length Lt of the bar capacitors 131. Accordingly the resistive element 135 couples adjacent transmission lines 131 to one another along substantially the whole length of each transmission line 131. The length of the resistive element 135 corresponds substantially to the distance between outer edges of the transmission lines 131.

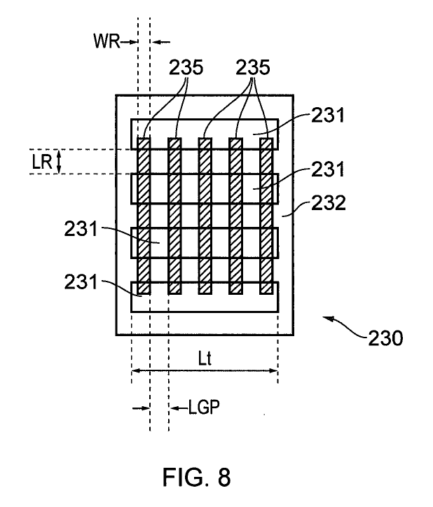

FIG. 8 shows an impedance-transforming device 230 according to a further embodiment of the present invention. Like features of the embodiment of FIG. 8 to those of the embodiment of FIG. 7 are shown with like reference signs prefixed with the numeral 2 instead of numeral 1. The device of FIG. 8 is similar to the embodiment of FIG. 7 except that the single resistive element 135 of the embodiment of FIG. 7 is replaced by five separate resistive elements of width WR much less than the length L of the transmission lines 231 provided by bar capacitor elements 231. The resistive elements 135 are provided at spaced apart locations along the length of the transmission lines with a gap of width LGP therebetween. The width WR and sheet resistance Rs of the elements 235 is selected so that the resistance of the elements 235 is sufficiently low to facilitate damping or elimination of odd-mode signals propagating along one or more of the transmission lines 231.

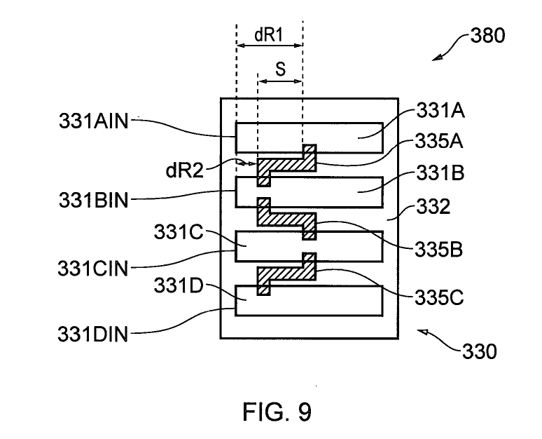

FIG. 9 shows an impedance-transforming device 330 according to a further embodiment of the present invention. Features of the embodiment of FIG. 9 similar to those of the embodiment of FIG. 8 are shown with like reference signs prefixed numeral 3 instead of numeral 2. In the device of FIG. 9 respective adjacent transmission lines 331A-D are coupled by means of a resistive element 335A-C at different respective distances from their input terminal 331AIN-DIN. Thus, a first resistive element 335A is connected to first transmission line 331A a distance dR1 from input terminal 331AIN thereof and to the second transmission line 331 B a distance dR2 from input terminal 331 BIN thereof. In the embodiment shown, dR1AR2. A second resistive element 335B is connected to second transmission line 331B a distance dR2 from input terminal 331BIN and to the third transmission line 331C a distance dR1 from input terminal 331CIN thereof. A third resistive element 335C is connected to third transmission line 331C a distance dR1 from input terminal 331CIN and to the fourth transmission line 331D a distance dR2 from its input terminal 331 DIN.

The difference between distances dR1 and dR2 (dR1−dR2) is given by parameter s, which may be called the offset. The embodiments of FIG. 5 and FIG. 8 correspond to values of s of substantially zero. For embodiments in which s is non-zero, such as that of FIG. 9, the value of s may be selected so as to cause attenuation, suppression or elimination of signals of substantially the same frequency travelling substantially in-phase along the transmission lines 331A-D (primarily pass band signals) and signals of substantially the same frequency that are travelling with a phase lag therebetween. In some embodiments, this may have the beneficial effect of stabilising the passband signals as well as attenuating or substantially eliminating odd-mode signals.

The offset s may be a suitable proportion of the length of the transmission lines 331, preferably at least 10%, and probably in the region of 20-50%. The arrangement need not be a dogleg, as shown, with right-angled bends, but could instead include diagonal lines, such as a straight angled line, or a curve: it is the offset that makes the difference.

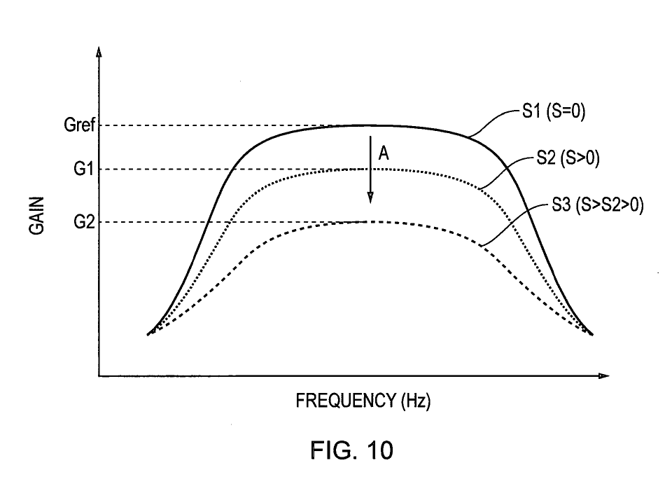

FIG. 10 is a plot of gain of a power amplifier 80 similar to that of the embodiment of FIG. 6 but in which input impedance matching device 30 of the embodiment of FIG. 6 has been replaced with the impedance matching device 330 of FIG. 9. For a value of dR1 equal to that of the embodiment of FIG. 6 and with s=0 the performance of the amplifier is similar to that of the embodiment of FIG. 6 and is shown by trace s1 of FIG. 10. It can be seen that the reference gain of the amplifier over the passband range of frequencies is given by Gref. However, as the value of s increases, the gain of the amplifier in the passband range of frequencies decreases, as shown by traces s2 and s3. The gain of the amplifier 80 over the passband range of frequencies therefore moves in the direction of arrow A of FIG. 10.

In the embodiments of FIG. 5 to FIG. 8, resistive elements 35, 135, 235 are shown as substantially continuous elements spanning several transmission lines. It is to be understood that in some alternative embodiments such as that of FIG. 9 the resistive elements may be provided as substantially discrete elements running between adjacent transmission lines and not running from one side of a transmission line to the other. Other arrangements are also useful. From the point of view of function there is no great difference, since the conductive lines 31 short-circuit any resistive material placed on top of them.

Some embodiments of the present invention have the advantage that unwanted oscillations in power amplifiers may be suppressed and in some circumstances substantially eliminated. Embodiments of the present invention may be implemented in certain known impedance matching devices in a convenient and cost-effective manner, providing substantial improvements in system performance.

Throughout the description and claims of this specification, the words “comprise” and “contain” and variations of them mean “including but not limited to”, and they are not intended to (and do not) exclude other components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

1. An impedance-transforming arrangement comprising a microwave power transistor and at least one intermediate impedance-transforming device, the device comprising:
a plurality of elongate microwave transmission lines provided in or on at least one dielectric substrate, each transmission line having a length and extending at least partially across or through the at least one dielectric substrate, the microwave transmission lines each having:
a first end coupled to the microwave power transistor; and
a second end providing a signal input terminal for the transmission line,
the transmission lines having a predetermined series inductance per unit length and, in combination with one or more electrically isolated conductive plates or layers, a predetermined shunt capacitance per unit length, such that each length of microwave transmission line together with the one or more conductive plates or layers has a predetermined characteristic impedance and phase constant,
wherein at least first and second transmission lines of the plurality of transmission lines are substantially directly coupled to one another by means of at least one resistive element, the resistive element providing a current flow path between the two transmission lines.

2. An arrangement according to claim 1, wherein the at least one resistive element is coupled to the first transmission line a first distance from the signal input terminal thereof and to the second transmission line a second distance from the signal input terminal thereof wherein at least one of the first and second distances is substantially non-zero.

3-4. (canceled)

5. An arrangement according to claim 2, wherein the first and second distances correspond to substantially equal electrical lengths.

6. (canceled)

7. An arrangement according to claim 1, wherein the plurality of elongate microwave transmission lines are provided in a spaced-apart side-by-side relationship, respective adjacent transmission lines being coupled to one another by means of the at least one resistive element.

8. An arrangement according to claim 7, wherein at least one resistive element is provided between each transmission line and its neighboring transmission line(s).

9. (canceled)

10. An arrangement according to claim 1, wherein each of the transmission lines of the device is coupled at its first end to the microwave power transistor by means of a respective bond wire or set of bond wires, the bond wire having a specified minimum practical length with an associated impedance, wherein the impedance of each respective bond wire is absorbed into the series impedance of the respective microwave transmission line, wherein the transistor has a plurality of gate bonding pads corresponding to the number of transmission lines, and the bond wires are bonded to the gate bonding pads.

11. (canceled)

12. An arrangement according to claim 1, wherein the intermediate impedance-transforming device is mounted upside down in a ‘flip-chip’ manner with respect to the microwave power transistors and each transmission line is coupled at the first end thereof to its respective one or more microwave power transistors by means of a solder bump.

13. An arrangement according to claim 1, wherein the at least one dielectric substrate of the intermediate impedance-transforming device has a dielectric constant in the range of 10 to 300.

14. An arrangement according to claim 1, wherein the plurality of microwave transmission lines of the device are provided on a single dielectric substrate.

15. An arrangement according to claim 1, wherein each microwave transmission line comprises one selected from a conductive microstrip transmission line, coplanar waveguide or a conductive stripline transmission line.

16-17. (canceled)

18. An arrangement according to claim 1, the at least one intermediate impedance-transforming device comprising a generally oblong slab of dielectric substrate with first and second opposed major surfaces, the first surface being metalized and the second surface bearing at least one microwave transmission line extending across it.

19. An arrangement according to claim 1, wherein one said at least one dielectric substrate is provided with a plurality of substantially parallel microwave transmission lines extending across it or through it.

20. An arrangement according to claim 19, wherein each microwave transmission line gives rise to substantially the same predetermined characteristic impedance and phase constant.

21. An arrangement according to claim 19, wherein at least a plurality of the microwave transmission lines are configured so as to give rise to different predetermined characteristic impedances and phase constants.

22. An arrangement according to claim 1, wherein the microwave power transistor is provided on a first dielectric substrate having a first dielectric constant, the at least one dielectric substrate of the impedance-transforming device having a dielectric constant greater than the first dielectric constant.

23. An arrangement according to claim 1, wherein the at least one intermediate impedance-transforming device is located on a gate terminal or input side of the transistor.

24. An arrangement according to claim 23, wherein a further intermediate impedance-transforming device is located on a drain terminal or output side of the transistor.

25. An arrangement according to claim 1, wherein the first end of each microwave transmission line is electrically connected to the transistor by a connection that is shorter in length than the microwave transmission line.

26. (canceled)

27. An arrangement according to claim 1, in combination with a primary matching network, the second end of each transmission line of the intermediate impedance-transforming device being coupled to a corresponding terminal of the primary matching network.

28. An arrangement according to claim 27, wherein the primary matching network includes at least one splitter portion configured to divide a single signal feed into two or more signal feeds.

29. An arrangement according to claim 27, wherein the primary matching network comprises a second dielectric substrate having a second dielectric constant.

30. An arrangement according to claim 29, wherein the second dielectric constant is less than that of the at least one dielectric substrate of the intermediate impedance-transforming device.

31. An arrangement according to claim 1, wherein the impedance-transforming arrangement operates at microwave frequencies of at least 10 GHz.

32. A method of impedance matching to a microwave power transistor, whereby at least first and second microwave transmission lines are each connected at a first end thereof to a gate terminal of a respective transistor, the at least first and second microwave transmission lines extending across or through a dielectric substrate, the microwave transmission lines each having a predetermined series inductance and, in combination with an electrically isolated conductive plate or layer, a predetermined shunt capacitance such that each microwave transmission line together with the conductive plate or layer has a predetermined characteristic impedance and phase constant, the method comprising coupling the first and second transmission lines substantially directly to one another by means of at least one resistive element, the at least one resistive element providing a current flow path between the two transmission lines such as to reduce or eliminate unstable oscillation.

33. (canceled)
